(19) United States
(12) Patent Application Publication
(10) Pub. No.: US 2024/0217014 A1
(43) Pub. Date: Jul. 4, 2024

(54) SOLDER PRINTING APPARATUS

(71) Applicant: Samsung Electronics Co., Ltd., Suwon-si (KR)

(72) Inventors: Seongchan HAN, Suwon-si (KR); Sangmyung LEE, Suwon-si (KR)

(73) Assignee: Samsung Electronics Co., Ltd., Suwon-si (KR)

(21) Appl. No.: 18/543,406

(22) Filed: Dec. 18, 2023

(30) Foreign Application Priority Data
Dec. 28, 2022 (KR) 10-2022-0187764

(51) Int. Cl. B23K 3/06; B23K 3/08; H05K 3/12

(52) U.S. Cl. CPC B23K 3/0638; B23K 3/08; H05K 3/1216; B23K 2101/42

(57) ABSTRACT

A solder printing apparatus including a printed circuit board feeding unit configured to sequentially feed a plurality of printed circuit boards, a solder paste printing unit configured to locate a solder mask on each of the printed circuit boards fed by the printed circuit board feeding unit and print solder paste on each of the printed circuit boards through an opening of the solder mask, a solder mask cleaning unit configured to clean residual solder from the solder mask after the solder paste is printed by the solder paste printing unit, and a control unit configured to control the solder paste printing unit and the solder mask cleaning unit, wherein the control unit is further configured to differently set a printing parameter of the solder paste printing unit for each of the printed circuit boards according to a cleaning cycle count set for the solder mask may be provided.

### CROSS-REFERENCE TO RELATED APPLICATION

This application is based on and claims priority under 35 U.S.C. § 119 to Korean Patent Application No. 10-2022-0187764, filed on Dec. 28, 2022, in the Korean Intellectual Property Office, the disclosure of which is incorporated by reference herein in its entirety.

### BACKGROUND

The inventive concepts relate to solder printing apparatuses, and more particularly, to solder printing apparatuses for increasing the uniformity of solder paste.

A flip-chip connection for a semiconductor chip (or a semiconductor device) involves printing solder paste on a certain region of a printed circuit board (PCB) and interconnecting the solder paste with an input/output pad of the semiconductor chip. Accordingly, reliability of the interconnection between the input/output pad of a semiconductor chip and a PCB may depend on the uniformity of solder paste.

### SUMMARY

The inventive concepts provide solder printing apparatuses for increasing the uniformity of solder paste.

According to an aspect of the inventive concepts, a solder printing apparatus may include a printed circuit board feeding unit configured to sequentially feed a plurality of printed circuit boards, a solder paste printing unit configured to locate a solder mask on each of the plurality of printed circuit boards fed by the printed circuit board feeding unit and print solder paste on each of the plurality of printed circuit boards through an opening of the solder mask, a solder mask cleaning unit configured to clean residual solder from the solder mask after the solder paste is printed by the solder paste printing unit, and a control unit configured to control the solder paste printing unit and the solder mask cleaning unit, wherein the control unit is further configured to differently set a printing parameter of the solder paste printing unit for each of the plurality of printed circuit boards according to a cleaning cycle count set for the solder mask.

According to another aspect of the inventive concepts, a solder printing apparatus may include a printed circuit board feeding unit configured to sequentially feed a plurality of printed circuit boards, a solder paste printing unit configured to locate a solder mask on each of the plurality of printed circuit boards sequentially fed by the printed circuit board feeding unit and print solder paste on each of the plurality of printed circuit boards, a solder mask cleaning unit configured to clean the solder mask, and a processor connected to the solder paste printing unit and the solder mask cleaning unit, wherein the plurality of printed circuit boards include a first printed circuit board group and a second printed circuit board group, and the processor is configured to obtain a first printing parameter and a second printing parameter according to a cleaning cycle count set for the solder mask, and transmit information to the solder paste printing unit, the information instructing to print the solder paste to the first printed circuit board group according to the first printing parameter and print the solder paste to the second printed circuit board group according to the second printing parameter.

According to a further aspect of the inventive concept, there is provided a solder printing apparatus including a printed circuit board feeding unit configured to sequentially feed a plurality of printed circuit boards, a solder paste printing unit configured to locate a solder mask on each of the plurality of printed circuit boards sequentially fed by the printed circuit board feeding unit and print solder paste on each of the plurality of printed circuit boards, a solder mask cleaning unit configured to clean the solder mask, and a processor connected to the solder paste printing unit and the solder mask cleaning unit, wherein the processor is configured to classify the plurality of printed circuit boards into first to n-th printed circuit board groups based on a remainder value when a number of printed circuit board feeding times is divided by a cleaning cycle count set for the solder mask, where “n” is a positive integer, obtain first to n-th printing parameters respectively used to print the solder paste on the first to n-th printed circuit board groups, and transmit information to the solder paste printing unit, the information instructing to print the solder paste to each of the first to n-th printed circuit board groups.

### BRIEF DESCRIPTION OF THE DRAWINGS

Example embodiments will be more clearly understood from the following detailed description taken in conjunction with the accompanying drawings in which:

FIG. 1 is a schematic block diagram of a solder printing apparatus according to an example embodiment;

FIG. 2 is a diagram of a solder paste printing unit of a solder printing apparatus, according to an example embodiment;

FIG. 3 is an enlarged diagram illustrating a printing parameter of a solder paste printing unit of a solder printing apparatus, according to an example embodiment;

FIG. 4 is a diagram of a solder mask cleaning unit of a solder printing apparatus, according to an example embodiment;

FIG. 5 is a diagram of a control unit of a solder printing apparatus, according to an example embodiment;

FIG. 6 is a diagram illustrating an algorithm by which a solder printing method using a solder printing apparatus is used, according to an example embodiment;

FIG. 7 is a diagram illustrating printing parameters used in the solder printing method of FIG. 6;

FIG. 8 is a diagram illustrating solder volume with respect to the printing parameter of FIG. 7;

FIG. 9 is a diagram illustrating an algorithm by which a solder printing method using a solder printing apparatus is used, according to an example embodiment;

FIG. 10 is a diagram illustrating a printing parameter used in the solder printing method of FIG. 9;

FIG. 11 is a diagram illustrating the uniformity of solder volume according to the feeding order of printed circuit boards (PCBs) fed after solder mask cleaning in FIG. 9; and

FIG. 12 is a diagram illustrating an algorithm by which a solder printing method using a solder printing apparatus is used, according to an example embodiment.

### DETAILED DESCRIPTION

Hereinafter, some example embodiments will be described with reference to the accompanying drawings. In the drawing, like reference characters denote like elements, and redundant descriptions thereof will be omitted.

While the term “same,” “equal” or “identical” or specific numbers is used or recited in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

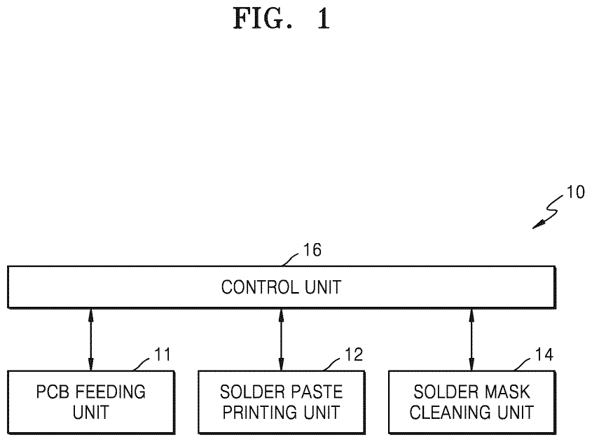

FIG. 1 is a schematic block diagram of a solder printing apparatus according to an example embodiment.

For example, a solder printing apparatus 10 according to an example embodiment of the inventive concepts may include a printed circuit board (PCB) feeding unit 11, a solder paste printing unit 12, a solder mask cleaning unit 14, and a control unit (or alternatively, controller) 16. The solder printing apparatus 10 may form a solder ball on a surface of a PCB. The solder printing apparatus 10 may be referred to as a screen printing machine.

The PCB feeding unit 11 may feed a PCB to the inside of the solder printing apparatus 10. The PCB feeding unit 11 may feed a PCB to the inside of the solder printing apparatus 10 by using a mechanical element, such as a moving rail or a pick-up portion. A PCB may be referred to as a printed circuit substrate.

The solder paste printing unit 12 may print solder on a PCB. The solder paste printing unit 12 may print solder by placing, on the PCB, a solder mask having an opening, pouring solder paste on the solder mask, and filling the opening of the solder mask with the solder by using a squeegee.

The solder mask cleaning unit 14 may clean a solder mask placed in the solder paste printing unit 12. The solder mask cleaning unit 14 may clean the solder mask and remove solder paste, which remains in the solder mask when or after the solder paste printing unit 12 prints solder.

The control unit 16 may control the PCB feeding unit 11, the solder paste printing unit 12, and the solder mask cleaning unit 14. The control unit 16 may be mechanically and electrically connected to the PCB feeding unit 11, the solder paste printing unit 12, and the solder mask cleaning unit 14.

The control unit 16 may count the number of PCB feeding times through the PCB feeding unit 11. The control unit 16 may set a cleaning cycle count for a solder mask. The control unit 16 may set a printing parameter for the solder paste printing unit 12.

As described below, the control unit 16 may set a printing parameter according to the feeding order of PCBs fed after solder mask cleaning. The control unit 16 may obtain different printing parameters for individual PCBs according to a cleaning cycle count for a solder mask.

The control unit 16 may transmit a signal indicating solder printing to the solder paste printing unit 12 according to different printing parameters obtained for individual PCBs. The control unit 16 may determine whether a solder mask is cleaned by the solder mask cleaning unit 14.

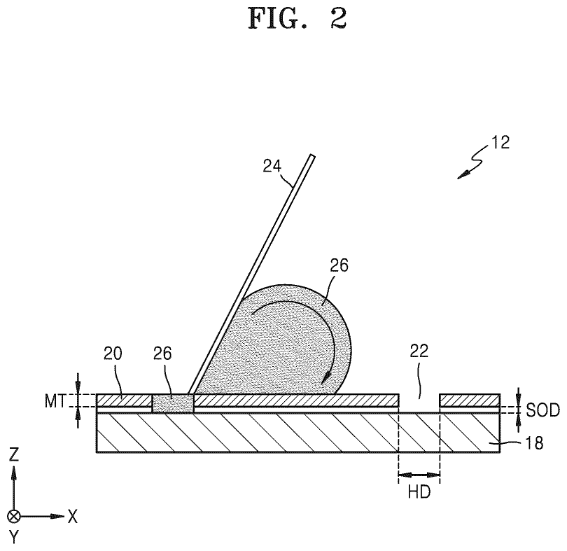

FIG. 2 is a diagram of a solder paste printing unit of a solder printing apparatus, according to an example embodiment.

For example, FIG. 2 illustrates the solder paste printing unit 12 of the solder printing apparatus 10 of FIG. 1. The solder paste printing unit 12 may have a solder mask 20 located on a PCB 18. In FIG. 2, the X direction and the Y direction may respectively correspond to a first horizontal direction and a second horizontal direction that are parallel with a surface of each of the PCB 18 and the solder mask 20.

The Y direction may be perpendicular to the X direction on the surface of each of the PCB 18 and the solder mask 20. The Z direction may correspond to a vertical direction that is perpendicular to the surface of each of the PCB 18 and the solder mask 20.

The solder mask 20 may be referred to as a stencil mask. The solder mask 20 may include a metal mask. The solder mask 20 may have a thickness MT. The thickness MT of the solder mask 20 may be tens to hundreds of micrometers. The solder mask 20 may include an opening 22. The opening 22 may have a diameter HD. The diameter HD of the opening 22 may be several to tens of millimeters. There may be a plurality of openings 22 in the solder mask 20.

A snap-off distance SOD may be set between the PCB 18 and the solder mask 20. The snap-off distance SOD may refer to a separation distance between the PCB 18 and the solder mask 20. The snap-off distance SOD may be several millimeters.

The solder paste printing unit 12 may pour solder paste 26 on the solder mask 20 and then move a squeegee 24 on the solder mask 20. The solder paste 26 on the solder mask 20 may rotate clockwise as shown by the arrow according to the movement of the squeegee 24.

As the squeegee 24 moves on the solder mask 20 in the X direction (the first horizontal direction), the opening 22 of the solder mask 20 may be filled with the solder paste 26. Although it is illustrated for convenience in FIG. 2 that the squeegee 24 moves in the X direction (the first horizontal direction), the squeegee 24 may also move in the Y direction (the second horizontal direction).

Accordingly, the solder paste 26 (or solder) may be printed on a portion of the PCB 18, which corresponds to the opening 22 of the solder mask 20. The solder paste 26 printed on the PCB 18 may be hardened in a subsequent process to form a solder ball.

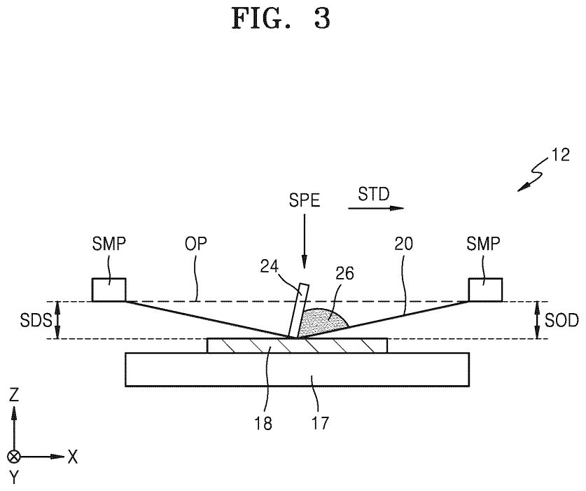

FIG. 3 is an enlarged diagram illustrating a printing parameter of a solder paste printing unit of a solder printing apparatus, according to an example embodiment.

For example, FIG. 3 illustrates a printing parameter of the solder paste printing unit 12 of the solder printing apparatus 10 of FIG. 1. As described above, the solder paste printing unit 12 may print the solder paste 26 on the PCB 18 located on a board support 17. The printing parameter influencing printing quality when the solder paste 26 is printed on the PCB 18 is described in detail below.

The PCB 18 may be fed by the PCB feeding unit 11 (in FIG. 1) onto the board support 17. The board support 17 may be moved up and down in the Z direction (the vertical direction) that is perpendicular to the surface of the PCB 18.

The solder mask 20 may be located on the PCB 18 and supported by a mask frame SMP. The snap-off distance SOD may be set between the solder mask 20 and the PCB 18. When the board support 17 is moved in the Z direction (the vertical direction) that is perpendicular to the surface of the PCB 18, the snap-off distance SOD may be adjusted.

The snap-off distance SOD shown in FIG. 3 is a maximum snap-off distance between the solder mask 20 and the PCB 18. When the snap-off distance SOD decreases, the height of the solder paste 26 printed on the PCB 18 may also decrease. When the snap-off distance SOD increases, the height of the solder paste 26 printed on the PCB 18 may also increase.

The squeegee 24 may be located on the solder mask 20. The squeegee 24 may move in the Z direction (the vertical direction) that is perpendicular to the surface of the PCB 18. A squeegee down distance SDS may be set between the squeegee 24 and the mask frame SMP.

The squeegee down distance SDS may correspond to a distance between an original position OP of the solder mask 20 and the lowest position of the solder mask 20 lowered by the squeegee 24. The squeegee down distance SDS may be minimized. When the squeegee down distance SDS is large, the solder mask 20 and the squeegee 24 may be easily damaged.

The solder paste 26 may be located on the solder mask 20. The squeegee 24 may move in the X direction (the first horizontal direction) and print the solder paste 26 on the PCB 18. The squeegee 24 may apply a squeegee pressure SPE to the solder mask 20.

The squeegee pressure SPE may be applied in the vertical direction (the Z direction) that is perpendicular to the surface of each of the solder mask 20 and the PCB 18. When the squeegee pressure SPE is adjusted, the height of the solder paste 26 printed on the PCB 18 may also be adjusted. The squeegee pressure SPE may determine the uniformity (volume uniformity) of the solder paste 26 printed on the PCB 18.

The squeegee 24 may move on the solder mask 20 at a squeegee speed STD. Referring to FIG. 3, the squeegee 24 may move at the squeegee speed STD in the first horizontal direction (the X direction) on the solder mask 20. Although it is illustrated for convenience that the squeegee 24 moves in the X direction (the first horizontal direction), the squeegee 24 may also move in the Y direction (the second horizontal direction).

The squeegee speed STD may depend on the thixotrophic behavior of the solder paste 26. The squeegee speed STD may determine the printing quality of the solder paste 26 on the PCB 18. The squeegee speed STD may determine the uniformity (volume uniformity) of the solder paste 26 printed on the PCB 18.

The squeegee 24 may move on the solder mask 20 at least once. The squeegee 24 may move on the solder mask 20 at least once and print the solder paste 26 on the PCB 18. The number of moves of the squeegee 24 (e.g., the number of printings) may determine the uniformity (volume uniformity) of the solder paste 26 printed on the PCB 18.

After the solder paste 26 is printed on the PCB 18, the solder mask 20 may be separated from the PCB 18. After the solder paste 26 is printed on the PCB 18, the solder mask 20 may return to the original position OP.

A separation speed by which the solder mask 20 is separated from the PCB 18 may greatly influence the printing quality. The separation speed may determine the uniformity (volume uniformity) of the solder paste 26 printed on the PCB 18.

As described above, when the solder paste printing unit 12 prints the solder paste 26 on the PCB 18, the printing parameter influencing the printing quality may include the squeegee down distance SDS, the snap-off distance SOD, the squeegee pressure SPE, the squeegee speed STD, a print count, and the separation speed.

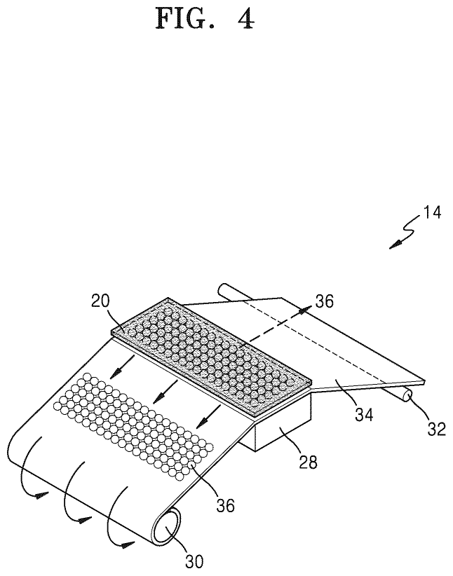

FIG. 4 is a diagram of a solder mask cleaning unit of a solder printing apparatus, according to an example embodiment.

For example, FIG. 4 illustrates the solder mask cleaning unit 14 of the solder printing apparatus 10 of FIG. 1. The solder mask cleaning unit 14 may include a cleaning paper support 28, a cleaning roller 30, and a cleaning paper feed support 32. After the solder paste 26 (in FIGS. 2 and 3) is printed on the PCB 18 (in FIGS. 2 and 3), the solder mask cleaning unit 14 may move the PCB 18 and clean the solder mask 20.

The solder mask cleaning unit 14 may supply a cleaning paper 34 to the back of the solder mask 20 by using the cleaning roller 30 and the cleaning paper feed support 32. The cleaning paper 34 may be horizontally moved in a −X direction by the cleaning roller 30 and wound around the cleaning roller 30. The cleaning paper 34 may be on the cleaning paper support 28 and located on the back of the solder mask 20. The board support 17 (in FIG. 3) may be used as the cleaning paper support 28.

The cleaning paper 34 horizontally moves in the −X direction while being in contact with the back of the solder mask 20, thereby cleaning the residual solder paste 36 from the back of the solder mask 20. The residual solder paste 36 may come off the solder mask 20 and may be wound around the cleaning roller 30. In some example embodiments, the cleaning paper 34 may be impregnated with a cleansing solution to increase a cleaning effect by the cleaning paper 34.

When the residual solder paste 36 is cleaned from the back of the solder mask 20 by the solder mask cleaning unit 14, solder uniformity (or solder paste uniformity) on the PCB 18 (in FIGS. 2 and 3) that is fed after a cleaning cycle may decrease. In other words, the uniformity of solder volume (or solder phase volume) on the PCB 18 (in FIGS. 2 and 3) that is fed after the cleaning cycle may decrease.

When the uniformity of solder volume (or solder phase volume) on the PCB 18 (in FIGS. 2 and 3) that is fed after the cleaning cycle decreases, the printing quality of solder paste on the PCB 18 (in FIGS. 2 and 3) may also decrease. Therefore, according to an example embodiment of the inventive concepts, the printing parameter described above may be differently set according to the PCB 18 (in FIGS. 2 and 3) that is fed after the cleaning cycle in order to increase the uniformity of solder volume (or solder phase volume) on the PCB 18 (in FIGS. 2 and 3). This is described in detail below.

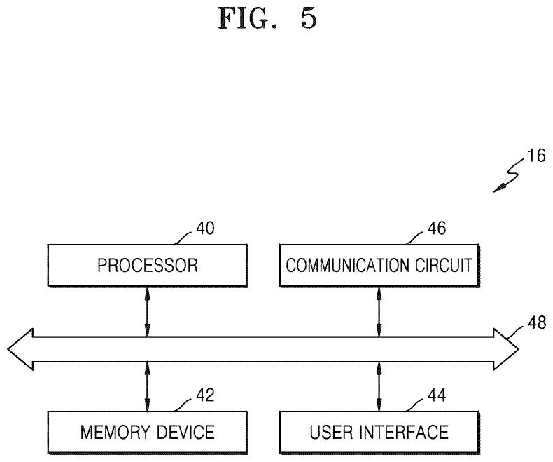

FIG. 5 is a diagram of a control unit of a solder printing apparatus, according to an example embodiment.

For example, FIG. 5 illustrates the control unit 16 of the solder printing apparatus 10 of FIG. 1. The control unit 16 may include a processor 40, a memory device 42, a user interface 44, and a communication circuit 46. In some example embodiments, except for the processor 40, at least one of the components described above of the control unit 16 may be omitted, or another component may be added to the control unit 16.

In some example embodiments, the components of the control unit 16 may be connected to one another and exchange data or signals with one another through a bus 48 and a general purpose input/output (GPIO), a serial peripheral interface (SPI), or a mobile industry processor interface (MIPI).

The memory device 42 may store the number of PCB feeding times and a cleaning cycle count for the solder mask 20 (in FIGS. 2 and 3). The memory device 42 may store various kinds of data. Data stored in the memory device 42 may be obtained, processed, or used by at least one component of the control unit 16 and may include software (e.g., instructions, programs, or the like).

The memory device 42 may include volatile memory and/or non-volatile memory. In an example embodiment, the memory device 42 may store instructions for allowing the processor 40 to perform an operation when software is executed by the processor 40. In some example embodiments, the memory device 42 may store a control parameter of the solder printing apparatus 10.

The communication circuit 46 may be connected to the bus 48 to communicate with the PCB feeding unit 11 (in FIG. 1), the solder paste printing unit 12 (in FIG. 1), and the solder mask cleaning unit 14 (in FIG. 1). In some example embodiments, the communication circuit 46 may communicate with other devices, such as a server, via a wireless or wired connection.

For example, the communication circuit 46 may perform wireless communication by using a method, such as enhanced Mobile Broadband (cMBB), Ultra Reliable Low-Latency Communications (URLLC), Massive Machine Type Communications (MMTC), Long-Term Evolution (LTE), LTE Advance (LTEA), New Radio (NR), Universal Mobile Telecommunications System (UMTS), Global System for Mobile communications (GSM), Code Division Multiple Access (CDMA), Wideband CDMA (WCDMA), Wireless Broadband (WiBro), Wireless Fidelity (WiFi), Bluetooth, Near Field Communication (NFC), Global Positioning System (GPS), or Global Navigation Satellite System (GNSS).

For example, the communication circuit 46 may perform wired communication by using a method, such as Universal Serial Bus (USB), High Definition Multimedia Interface (HDMI), Recommended Standard-232 (RS-232), or Plain Old Telephone Service (POTS).

The processor 40 may be connected to the memory device 42, the communication circuit 46, and the user interface 44 through the bus 48. The processor 40 may control at least one component of a device connected to the processor 40 by running software (e.g., instructions or programs). The processor 40 may perform various arithmetic operations, processing, data generation, or the like. The processor 40 may load data or the like from the memory device 42 or store data or the like in the memory device 42. According to some example embodiments, the processor 40 may be implemented as processing circuitry, such as hardware including logic circuits, a hardware/software combination executing software, or a combination thereof. For example, the processing circuitry may include, but is not limited to, a central processing unit (CPU), an arithmetic logic unit (ALU), a digital signal processor, a microcomputer, a field programmable gate array (FPGA), programmable logic unit, a microprocessor, application-specific integrated circuit (ASIC), etc.

The processor 40 may count and store the number of PCB feeding times (e.g., the number of times that a PCB is fed by a PCB feeding unit). The processor 40 may differently set a printing parameter of a solder paste printing unit for each PCB according to a cleaning cycle count for a solder mask. The processor 40 may set the printing parameter according to the feeding order of PCBs fed after solder mask cleaning.

The processor 40 may obtain a different printing parameter for each PCB according to a cleaning cycle count for a solder mask and transmit a signal instructing to perform solder printing according to the printing parameter differently obtained for each PCB.

The user interface 44 may be connected to the memory device 42, the communication circuit 46, and the processor 40. The user interface 44 may receive an input from a user and output (or display) information to the user. In an example embodiment, the user interface 44 may include an input device and/or an output device. The input device may transmit information from the outside of the control unit 16 to at least one component of the control unit 16.

For example, the input device may include a mouse, a keyboard, or a touch pad. The output device may provide a user with various pieces of information of the control unit 16 in a visual/auditory form. For example, the output device may include a display, a projector, a hologram device, or a speaker. In an example embodiment, the user interface 44 may receive information for controlling the control unit 16 from a user.

The control unit 16 having the configuration described above may differently set the printing parameter of the solder paste printing unit 12 (in FIG. 1) for each PCB 18 (in FIGS. 2 and 3), which is fed by the PCB feeding unit 11 (in FIG. 1) described above, according to a cleaning cycle count set for a solder mask. The printing parameter may include at least one selected from the group consisting of a squeegee down distance, a squeegee pressure, a squeegee speed, and a print count

As described above, the printing parameter may include a snap-off distance between a PCB and a solder mask. As described above, the printing parameter may include a separation speed at which the solder mask is separated from the PCB after solder paste is printed on the PCB.

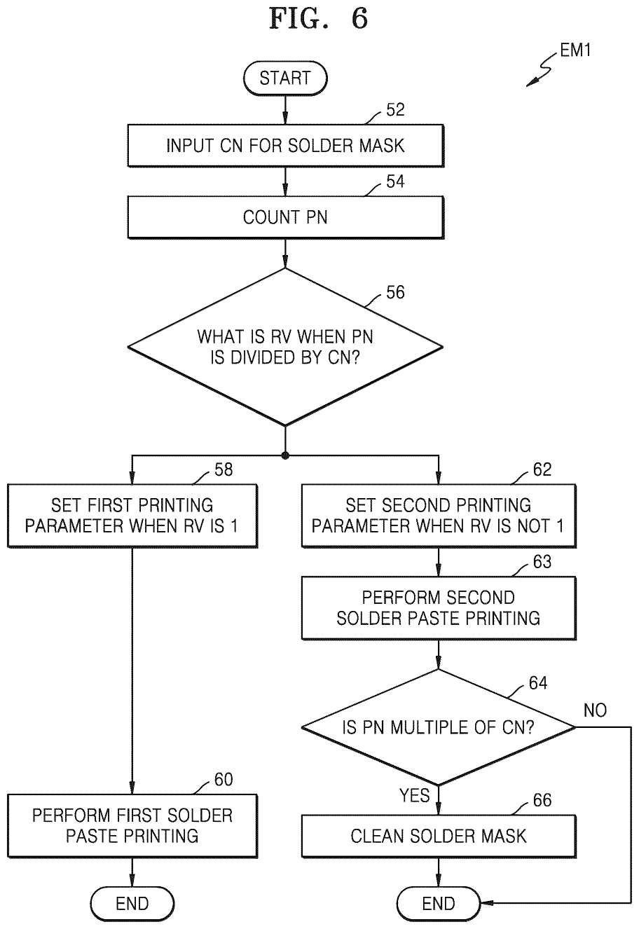

FIG. 6 is a diagram illustrating an algorithm by which a solder printing method using a solder printing apparatus is used, according to an example embodiment.

For example, an algorithm EM1 may be applied to software or a program, which is included in the control unit 16 (e.g., the processor 40) of the solder printing apparatus 10 (of FIG. 1) described above. A solder printing method performed by the solder printing apparatus 10 (of FIG. 1) by using the algorithm EM1 is described below. Here, reference numerals in FIGS. 1 to 5 are used in the description below, and like reference numerals denote like components in FIGS. 1 to 5.

After solder printing is started, a cleaning cycle count CN for the solder mask 20 may be input to the control unit 16 in operation 52. The cleaning cycle count CN may be arbitrarily set by a user. Here, for convenience of description, the cleaning cycle count CN is set to 5.

Continuously, the number of PCB feeding times PN may be counted using the control unit 16 in operation 54. The number of PCB feeding times PN (e.g., the number of times a PCB is fed and put under the solder mask 20) may be counted by the control unit 16.

A plurality of PCBs 18 may be sequentially fed to the inside of the solder printing apparatus 10 by the PCB feeding unit 11, and the number of PCB feeding times PN may be counted by the control unit 16. Here, for convenience of description, the maximum value of the number of PCB feeding times PN is set to 100. The number of PCB feeding times PN may be stored in the processor 40 or the memory device 42.

Subsequently, the control unit 16 may divide the number of PCB feeding times PN by the cleaning cycle count CN and produce a remainder value RV in operation 56. For example, assuming that the cleaning cycle count CN is 5 and the maximum value of the number of PCB feeding times PN is 100, the remainder value RV is described.

When the number of PCB feeding times PN is 1, 6, 11, 16, . . . , or 96, the remainder value RV may be 1. When the number of PCB feeding times PN is 2, 7, 12, 17, . . . , or 97, the remainder value RV may be 2. When the number of PCB feeding times PN is 3, 8, 13, 18, . . . , or 98, the remainder value RV may be 3. When the number of PCB feeding times PN is 4, 9, 14, 19, . . . , or 99, the remainder value RV may be 4. When the number of PCB feeding times PN is 5, 10, 15, 20, . . . , or 100, the remainder value RV may be 0.

PCBs corresponding to the remainder value RV of 1 may be classified into a first PCB group. When the remainder value RV is 1, a first printing parameter may be set in the control unit 16 in operation 58. The processor 40 of the control unit 16 may obtain and set the first printing parameter to print solder paste on the first PCB group according to the cleaning cycle count CN set for the solder mask 20.

The first printing parameter may include at least one selected from a squeegee down distance, a squeegee pressure, a squeegee speed, and a print count, as described above. The first printing parameter may include a snap-off distance or a separation speed, as described above.

When the remainder value RV is 1, a first solder paste printing may be performed on a PCB according to the first printing parameter in operation 60. The processor 40 of the control unit 16 may transmit, to the solder paste printing unit 12, information instructing to perform the first solder paste printing on the first PCB group according to the first printing parameter. After the first solder paste printing is performed, the solder printing may be terminated.

PCBs corresponding to the case where the remainder value RV is not 1 may be classified into a second PCB group. The second PCB group may include more PCBs than the first PCB group. When the remainder value RV is not 1, a second printing parameter may be set in the control unit 16 in operation 62. The processor 40 of the control unit 16 may obtain and set the second printing parameter to print solder paste on the second PCB group according to the cleaning cycle count CN set for the solder mask 20.

The second printing parameter may be different from the first printing parameter. The second printing parameter may include at least one selected from a squeegee down distance, a squeegee pressure, a squeegee speed, and a print count, as described above. The second printing parameter may include a snap-off distance or a separation speed, as described above.

When the remainder value RV is not 1, a second solder paste printing may be performed on a PCB according to the second printing parameter in operation 63. The processor 40 of the control unit 16 may transmit, to the solder paste printing unit 12, information instructing to perform the second solder paste printing on the second PCB group according to the second printing parameter.

Continuously, when the remainder value RV is not 1, the control unit 16 may calculate whether the number of PCB feeding times PN is a multiple of the cleaning cycle count CN set for the solder mask 20 in operation 64.

When the number of PCB feeding times PN is a multiple of the cleaning cycle count CN, the solder mask 20 is cleaned by the solder mask cleaning unit 14 in operation 66. When the number of PCB feeding times PN is 5, 10, 15, 20, . . . , or 100, the number of PCB feeding times PN may be a multiple of the cleaning cycle count CN. When the number of PCB feeding times PN is a multiple of the cleaning cycle count CN, the remainder value RV may be 0.

The solder printing may be terminated after the solder mask 20 is cleaned. When the number of PCB feeding times PN is not a multiple of the cleaning cycle count CN, the solder printing may be terminated without cleaning the solder mask 20.

As described above, the algorithm EM1 used by the solder printing apparatus 10 (of FIG. 1) may set the first and second printing parameters according to the feeding order of PCBs fed after solder mask cleaning and perform solder printing based on the first and second printing parameters. Accordingly, the solder printing apparatus 10 may increase the uniformity of solder volume (or solder paste volume) on a PCB fed after a cleaning cycle of a solder mask.

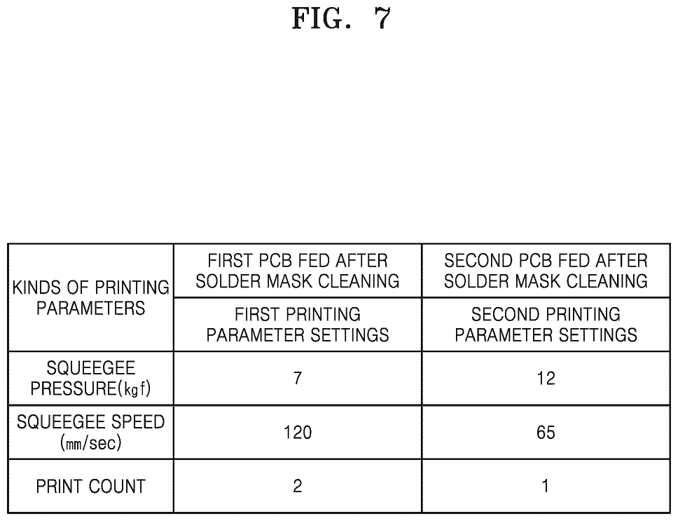

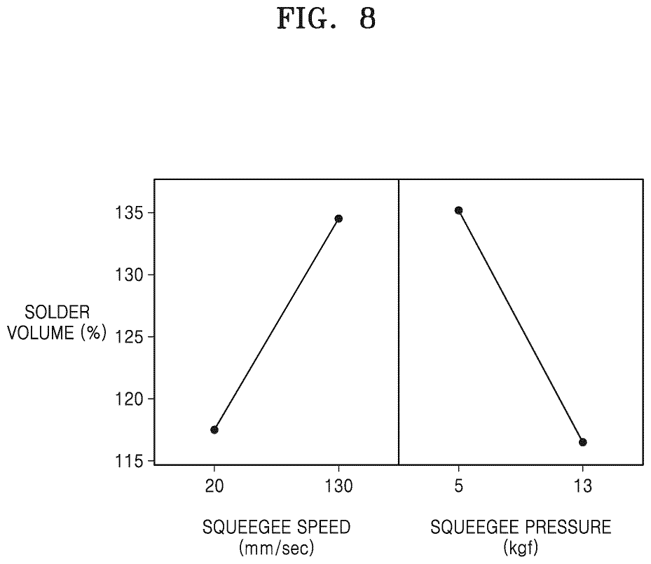

FIG. 7 is a diagram illustrating printing parameters used in the solder printing method of FIG. 6, and FIG. 8 is a diagram illustrating solder volume with respect to the printing parameters of FIG. 7.

For example, FIG. 7 illustrates the first and second printing parameters used in the algorithm EM1 of FIG. 6, according to an example embodiment. As described above with reference to FIG. 6, when the remainder value RV is 1, the first printing parameter may be set in the control unit 16. When the remainder value RV is 1, the first solder paste printing may be performed on a PCB in the first PCB group according to the first printing parameter.

The first printing parameter may include a first squeegee pressure, a first squeegee speed, and a first print count (or a first squeegee count). The first squeegee pressure of the first printing parameter may be 7 kgf, the first squeegee speed of the first printing parameter may be 120 mm/sec, and the first print count of the first printing parameter may be 2.

As described above with reference to FIG. 6, when the remainder value RV is not 1, the second printing parameter may be set in the control unit 16. When the remainder value RV is not 1, the second solder paste printing may be performed on a PCB in the second PCB group according to the second printing parameter.

The second printing parameter may include a second squeegee pressure, a second squeegee speed, and a second print count (or a second squeegee count). The second squeegee pressure of the second printing parameter may be 12 Kg/f, the second squeegee speed of the second printing parameter may be 65 mm/sec, and the second print count of the second printing parameter may be 1.

As described above, the values of the first and second printing parameters used in the algorithm EM1 may be different from each other. For instance, the first squeegee pressure of the first printing parameter may be less than the second squeegee pressure of the second printing parameter. The first squeegee speed of the first printing parameter may be greater than the second squeegee speed of the second printing parameter.

The value of each element of the first printing parameter is different from the value of a corresponding element of the second parameter because the volume of solder printed on a PCB is different according to each element of a printing parameter.

As shown in FIG. 8, when the squeegee speed of a solder printing apparatus increases, solder volume on a PCB may also increase. When the squeegee pressure of the solder printing apparatus increases, the solder volume on the PCB may decrease.

In a solder printing apparatus, a squeegee pressure needs to decrease when a squeegee speed increases in order to increase the uniformity of solder volume on a PCB. In a solder printing apparatus, a squeegee pressure needs to increase when a squeegee speed decreases in order to increase the uniformity of solder volume on a PCB.

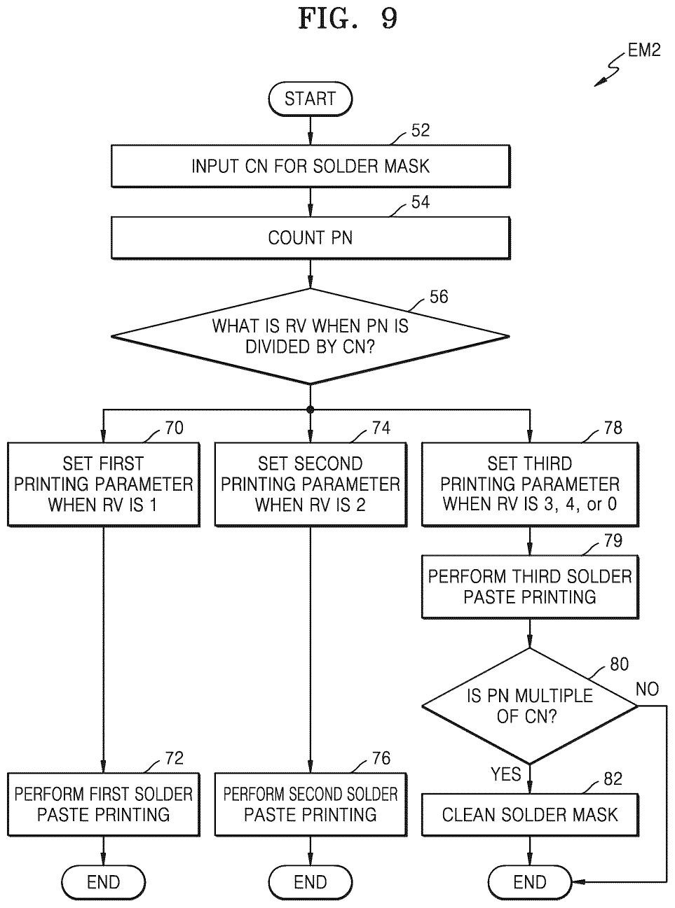

FIG. 9 is a diagram illustrating an algorithm by which a solder printing method using a solder printing apparatus is used, according to an example embodiment.

For example, an algorithm EM2 may be applied to software or a program, which is included in the control unit 16 (e.g., the processor 40) of the solder printing apparatus 10 (of FIG. 1) described above. A solder printing method performed by the solder printing apparatus 10 (of FIG. 1) by using the algorithm EM2 is described below. Here, reference numerals in FIGS. 1 to 5 are used in the description below, and like reference numerals denote like components in FIGS. 1 to 5.

After solder printing is started, the cleaning cycle count CN for the solder mask 20 may be input to the control unit 16 in operation 52. The cleaning cycle count CN may be arbitrarily set by a user. Here, for convenience of description, the cleaning cycle count CN is set to 5.

Continuously, the number of PCB feeding times PN may be counted using the control unit 16 in operation 54. The number of PCB feeding times PN (e.g., the number of times a PCB is fed and put under the solder mask 20) may be counted by the control unit 16.

A plurality of PCBs 18 may be sequentially fed to the inside of the solder printing apparatus 10 by the PCB feeding unit 11, and the number of PCB feeding times PN may be counted by the control unit 16. Here, for convenience of description, the maximum value of the number of PCB feeding times PN is set to 100. The number of PCB feeding times PN may be stored in the processor 40 or the memory device 42.

Subsequently, the control unit 16 may divide the number of PCB feeding times PN by the cleaning cycle count CN and produce the remainder value RV in operation 56. For example, assuming that the cleaning cycle count CN is 5 and the maximum value of the number of PCB feeding times PN is 100, the remainder value RV is described.

When the number of PCB feeding times PN is 1, 6, 11, 16, . . . , or 96, the remainder value RV may be 1. When the number of PCB feeding times PN is 2, 7, 12, 17, . . . , or 97, the remainder value RV may be 2. When the number of PCB feeding times PN is 3, 8, 13, 18, . . . , or 98, the remainder value RV may be 3. When the number of PCB feeding times PN is 4, 9, 14, 19, . . . , or 99, the remainder value RV may be 4. When the number of PCB feeding times PN is 5, 10, 15, 20, . . . , or 100, the remainder value RV may be 0.

PCBs corresponding to the remainder value RV of 1 may be classified into a first PCB group. When the remainder value RV is 1, a first printing parameter may be set in the control unit 16 in operation 70. The processor 40 of the control unit 16 may obtain and set the first printing parameter to print solder paste on the first PCB group according to the cleaning cycle count CN set for the solder mask 20.

The first printing parameter may include at least one selected from a squeegee down distance, a squeegee pressure, a squeegee speed, and a print count, as described above. The first printing parameter may include a snap-off distance or a separation speed, as described above.

When the remainder value RV is 1, a first solder paste printing may be performed on a PCB according to the first printing parameter in operation 72. The processor 40 of the control unit 16 may transmit, to the solder paste printing unit 12, information instructing to perform the first solder paste printing on the first PCB group according to the first printing parameter. After the first solder paste printing is performed, the solder printing may be terminated.

PCBs corresponding to the case where the remainder value RV is 2 may be classified into a second PCB group. When the remainder value RV is 2, a second printing parameter may be set in the control unit 16 in operation 74. The processor 40 of the control unit 16 may obtain and set the second printing parameter to print solder paste on the second PCB group according to the cleaning cycle count CN set for the solder mask 20.

The second printing parameter may include at least one selected from a squeegee down distance, a squeegee pressure, a squeegee speed, and a print count, as described above. The second printing parameter may include a snap-off distance or a separation speed, as described above.

When the remainder value RV is 2, a second solder paste printing may be performed on a PCB according to the second printing parameter in operation 76. The processor 40 of the control unit 16 may transmit, to the solder paste printing unit 12, information instructing to perform the second solder paste printing on the second PCB group according to the second printing parameter. After the second solder paste printing is performed, the solder printing may be terminated.

PCBs corresponding to the case where the remainder value RV is 3, 4, or 0 may be classified into a third PCB group. The third PCB group may include more PCBs than the first and second PCB groups. When the remainder value RV is 3, 4, or 0, a third printing parameter may be set in the control unit 16 in operation 78. The processor 40 of the control unit 16 may obtain and set the third printing parameter to print solder paste on the third PCB group according to the cleaning cycle count CN set for the solder mask 20.

The third printing parameter may be different from the first printing parameter and the second printing parameter. The third printing parameter may include at least one selected from a squeegee down distance, a squeegee pressure, a squeegee speed, and a print count, as described above. The third printing parameter may include a snap-off distance or a separation speed, as described above.

When the remainder value RV is 3, 4, or 0, a third solder paste printing may be performed according to the third printing parameter in operation 79. The processor 40 of the control unit 16 may transmit, to the solder paste printing unit 12, information instructing to perform the third solder paste printing on the third PCB group according to the third printing parameter.

Continuously, when the remainder value RV is 3, 4, or 0, the control unit 16 may calculate whether the number of PCB feeding times PN is a multiple of the cleaning cycle count CN set for the solder mask 20 in operation 80.

When the number of PCB feeding times PN is a multiple of the cleaning cycle count CN, the solder mask 20 is cleaned by the solder mask cleaning unit 14 in operation 82. When the number of PCB feeding times PN is 5, 10, 15, 20, . . . , or 100, the number of PCB feeding times PN may be a multiple of the cleaning cycle count CN. When the number of PCB feeding times PN is a multiple of the cleaning cycle count CN, the remainder value RV may be 0.

The solder printing may be terminated after the solder mask 20 is cleaned. When the number of PCB feeding times PN is not a multiple of the cleaning cycle count CN, the solder printing may be terminated without cleaning the solder mask 20.

As described above, the algorithm EM2 used by the solder printing apparatus 10 (of FIG. 1) may set the first to third printing parameters according to the feeding order of PCBs fed after solder mask cleaning and perform solder printing based on the first to third printing parameters. Accordingly, the solder printing apparatus 10 may increase the uniformity of solder volume (or solder paste volume) on a PCB fed after a cleaning cycle of a solder mask.

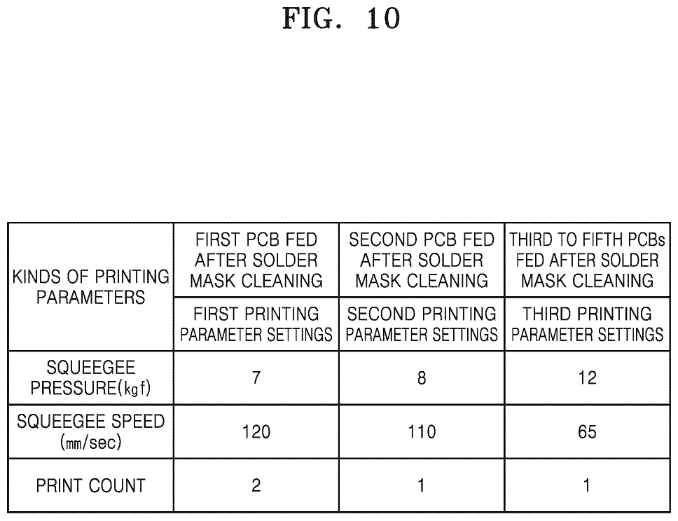

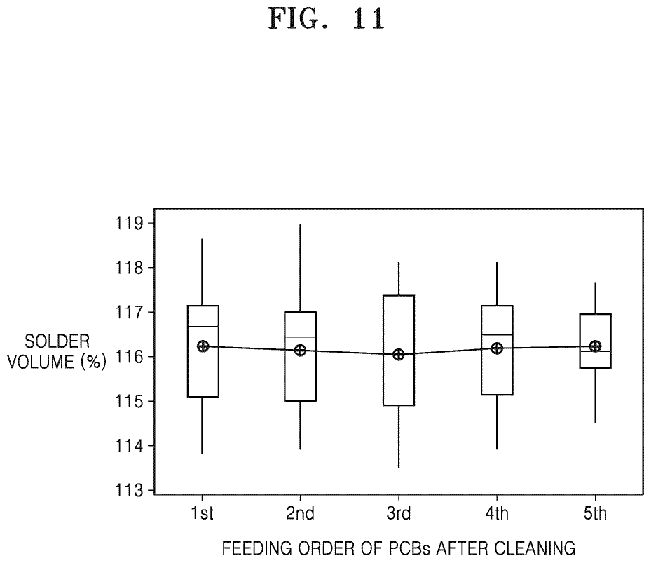

FIG. 10 is a diagram illustrating a printing parameter used in the solder printing method of FIG. 9, and FIG. 11 is a diagram illustrating the uniformity of solder volume according to the feeding order of PCBs fed after solder mask cleaning in FIG. 9.

For example, FIG. 10 illustrates the first to third printing parameters used in the algorithm EM2 of FIG. 9, according to an example embodiment. As described above with reference to FIG. 9, when the remainder value RV is 1, the first printing parameter may be set in the control unit 16. When the remainder value RV is 1, the first solder paste printing may be performed on a PCB in the first PCB group according to the first printing parameter.

The first printing parameter may include a first squeegee pressure, a first squeegee speed, and a first print count (or a first squeegee count). The first squeegee pressure of the first printing parameter may be 7 kgf, the first squeegee speed of the first printing parameter may be 120 mm/sec, and the first print count of the first printing parameter may be 2.

As described above with reference to FIG. 9, when the remainder value RV is 2, the second printing parameter may be set in the control unit 16. When the remainder value RV is 2, the second solder paste printing may be performed on a PCB in the second PCB group according to the second printing parameter.

The second printing parameter may include a second squeegee pressure, a second squeegee speed, and a second print count (or a second squeegee count). The second squeegee pressure of the second printing parameter may be 8 kgf, the second squeegee speed of the second printing parameter may be 110 mm/sec, and the second print count of the second printing parameter may be 1.

As described above with reference to FIG. 9, when the remainder value RV is 3, 4, or 0, the third printing parameter may be set in the control unit 16. When the remainder value RV is 3, 4 or 0, the third solder paste printing may be performed on a PCB in the third PCB group according to the third printing parameter.

The third printing parameter may include a third squeegee pressure, a third squeegee speed, and a third print count (or a third squeegee count). The third squeegee pressure of the third printing parameter may be 12 kgf, the third squeegee speed of the third printing parameter may be 65 mm/sec, and the third print count of the third printing parameter may be 1.

As described above, the values of the first to third printing parameters used in the algorithm EM2 of FIG. 9 may be different from one another. For instance, the third squeegee pressure of the third printing parameter may be greater than each of the respective first and second squeegee pressures of the first and second printing parameters. The third squeegee speed of the third printing parameter may be less than each of the respective first and second squeegee speeds of the first and second printing parameters.

The values of the respective elements of the first to third printing parameters are different from one another because the volume of solder printed on a PCB is different according to each element of a printing parameter. FIG. 11 is provided to describe the uniformity of solder volume according to the feeding order of PCBs fed after solder mask cleaning. As shown in FIG. 11, the solder volume does not significantly change with respect to the feeding order of PCBs fed after solder mask cleaning in a solder printing apparatus. In a solder printing apparatus according to according to some example embodiments of the inventive concepts, a printing parameter may be differently set according to the feeding order of PCBs fed after solder mask cleaning, and accordingly, the uniformity of solder volume according to the feeding order of PCBs fed after the solder mask cleaning may be increased.

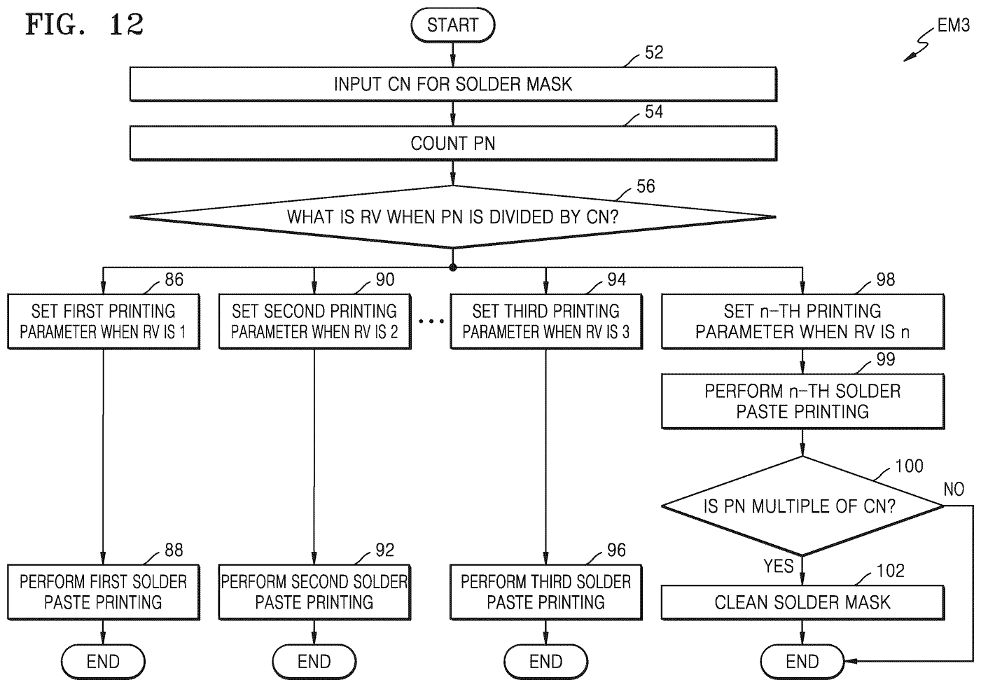

FIG. 12 is a diagram illustrating an algorithm by which a solder printing method using a solder printing apparatus is used, according to an example embodiment.

For example, an algorithm EM3 may be applied to software or a program, which is included in the control unit 16 (e.g., the processor 40) of the solder printing apparatus 10 (of FIG. 1) described above. A solder printing method performed by the solder printing apparatus 10 (of FIG. 1) by using the algorithm EM3 is described below. Here, reference numerals in FIGS. 1 to 5 are used in the description below, and like reference numerals denote like components in FIGS. 1 to 5.

After solder printing is started, the cleaning cycle count CN for the solder mask 20 may be input to the control unit 16 in operation 52. The cleaning cycle count CN may be arbitrarily set by a user. Here, for convenience of description, the cleaning cycle count CN is set to any positive integer.

Continuously, the number of PCB feeding times PN may be counted using the control unit 16 in operation 54. The number of PCB feeding times PN (e.g., the number of times a PCB is fed and put under the solder mask 20) may be counted by the control unit 16.

A plurality of PCBs 18 may be sequentially fed to the inside of the solder printing apparatus 10 by the PCB feeding unit 11, and the number of PCB feeding times PN may be counted by the control unit 16. The number of PCB feeding times PN may be stored in the processor 40 or the memory device 42.

Subsequently, the control unit 16 may divide the number of PCB feeding times PN by the cleaning cycle count CN and produce the remainder value RV in operation 56. For example, assuming that the cleaning cycle count CN is 5 and the maximum value of the number of PCB feeding times PN is 100, the remainder value RV is described.

When the number of PCB feeding times PN is 1, 6, 11, 16, . . . , or 96, the remainder value RV may be 1. When the number of PCB feeding times PN is 2, 7, 12, 17, . . . , or 97, the remainder value RV may be 2. When the number of PCB feeding times PN is 3, 8, 13, 18, . . . , or 98, the remainder value RV may be 3. When the number of PCB feeding times PN is 4, 9, 14, 19, . . . , or 99, the remainder value RV may be 4. When the number of PCB feeding times PN is 5, 10, 15, 20, . . . , or 100, the remainder value RV may be 0.

PCBs corresponding to the remainder value RV of 1 may be classified into a first PCB group. When the remainder value RV is 1, a first printing parameter may be set in the control unit 16 in operation 86. The processor 40 of the control unit 16 may obtain and set the first printing parameter to print solder paste on the first PCB group according to the cleaning cycle count CN set for the solder mask 20.

The first printing parameter may include at least one selected from a squeegee down distance, a squeegee pressure, a squeegee speed, and a print count, as described above. The first printing parameter may include a snap-off distance or a separation speed, as described above.

When the remainder value RV is 1, a first solder paste printing may be performed on a PCB according to the first printing parameter in operation 88. The processor 40 of the control unit 16 may transmit, to the solder paste printing unit 12, information instructing to perform the first solder paste printing on the first PCB group according to the first printing parameter. After the first solder paste printing is performed, the solder printing may be terminated.

PCBs corresponding to the case where the remainder value RV is 2 may be classified into a second PCB group. When the remainder value RV is 2, a second printing parameter may be set in the control unit 16 in operation 90. The processor 40 of the control unit 16 may obtain and set the second printing parameter to print solder paste on the second PCB group according to the cleaning cycle count CN set for the solder mask 20.

The second printing parameter may include at least one selected from a squeegee down distance, a squeegee pressure, a squeegee speed, and a print count, as described above. The second printing parameter may include a snap-off distance or a separation speed, as described above.

When the remainder value RV is 2, a second solder paste printing may be performed on a PCB according to the second printing parameter in operation 92. The processor 40 of the control unit 16 may transmit, to the solder paste printing unit 12, information instructing to perform the second solder paste printing on the second PCB group according to the second printing parameter. After the second solder paste printing is performed, the solder printing may be terminated.

PCBs corresponding to the case where the remainder value RV is 3 may be classified into a third PCB group. When the remainder value RV is 3, a third printing parameter may be set in the control unit 16 in operation 94. The processor 40 of the control unit 16 may obtain and set the third printing parameter to print solder paste on the third PCB group according to the cleaning cycle count CN set for the solder mask 20.

The third printing parameter may include at least one selected from a squeegee down distance, a squeegee pressure, a squeegee speed, and a print count, as described above. The third printing parameter may include a snap-off distance or a separation speed, as described above.

When the remainder value RV is 3, a third solder paste printing may be performed on a PCB according to the third printing parameter in operation 96. The processor 40 of the control unit 16 may transmit, to the solder paste printing unit 12, information instructing to perform the third solder paste printing on the third PCB group according to the third printing parameter. After the third solder paste printing is performed, the solder printing may be terminated.

PCBs corresponding to the case where the remainder value RV is “n” (where “n” is a positive integer) may be classified into an n-th PCB group. The n-th PCB group may include more PCBs than each of the first to third PCB groups. When the remainder value RV is “n”, an n-th printing parameter may be set in the control unit 16 in operation 98. The processor 40 of the control unit 16 may obtain and set the n-th printing parameter to print solder paste on the n-th PCB group according to the cleaning cycle count CN set for the solder mask 20.

The n-th printing parameter may be different from an (n−1)-th or less printing parameter (e.g., the first to third printing parameters). The n-th printing parameter may include at least one selected from a squeegee down distance, a squeegee pressure, a squeegee speed, and a print count, as described above. The n-th printing parameter may include a snap-off distance or a separation speed, as described above.

When the remainder value RV is “n”, an n-th solder paste printing may be performed according to the n-th printing parameter in operation 99. The processor 40 of the control unit 16 may transmit, to the solder paste printing unit 12, information instructing to perform the n-th solder paste printing on the n-th PCB group according to the n-th printing parameter.

Continuously, when the remainder value RV is “n”, the control unit 16 may calculate whether the number of PCB feeding times PN is a multiple of the cleaning cycle count CN set for the solder mask 20 in operation 100.

When the number of PCB feeding times PN is a multiple of the cleaning cycle count CN, the solder mask 20 is cleaned by the solder mask cleaning unit 14 in operation 102. When the number of PCB feeding times PN is 5, 10, 15, 20, . . . , or 100, the number of PCB feeding times PN may be a multiple of the cleaning cycle count CN. When the number of PCB feeding times PN is a multiple of the cleaning cycle count CN, the remainder value RV may be 0.

The solder printing may be terminated after the solder mask 20 is cleaned. When the number of PCB feeding times PN is not a multiple of the cleaning cycle count CN, the solder printing may be terminated without cleaning the solder mask 20.

As described above, in the algorithm EM3 used by the solder printing apparatus 10 (of FIG. 1), the first PCB group among the first to n-th PCB groups may refer to a first PCB that is fed after solder mask cleaning. The n-th PCB group among the first to n-th PCB groups may refer to an n-th PCB that is fed after the solder mask cleaning.

As described above, the algorithm EM3 used by the solder printing apparatus 10 (of FIG. 1) may set the first to n-th printing parameters according to the feeding order of PCBs fed after solder mask cleaning and perform solder printing based on the first to n-th printing parameters. Accordingly, the solder printing apparatus 10 may increase the uniformity of solder volume (or solder paste volume) on a PCB fed after a cleaning cycle of a solder mask.

While the inventive concepts have been particularly shown and described with reference to some example embodiments thereof, it will be understood that various changes in form and details may be made therein without departing from the spirit and scope of the following claims.

What is claimed is:

1. A solder printing apparatus comprising:
a printed circuit board feeding unit configured to sequentially feed a plurality of printed circuit boards;
a solder paste printing unit configured to locate a solder mask on each of the plurality of printed circuit boards fed by the printed circuit board feeding unit and print solder paste on each of the plurality of printed circuit boards through an opening of the solder mask;
a solder mask cleaning unit configured to clean residual solder from the solder mask after the solder paste is printed by the solder paste printing unit; and
a control unit configured to control the solder paste printing unit and the solder mask cleaning unit,
wherein the control unit is further configured to differently set a printing parameter of the solder paste printing unit for each of the plurality of printed circuit boards according to a cleaning cycle count set for the solder mask.

2. The solder printing apparatus of claim 1, wherein the printing parameter includes at least one selected from the group consisting of a squeegee down distance, a squeegee pressure, a squeegee speed, and a print count.

3. The solder printing apparatus of claim 1, wherein the printing parameter includes a snap-off distance between each of the plurality of printed circuit boards and the solder mask.

4. The solder printing apparatus of claim 1, wherein the printing parameter includes a separation speed at which the solder mask is separated from each of the plurality of printed circuit boards after the solder paste is printed.

5. The solder printing apparatus of claim 1, wherein the control unit includes a processor configured to set the printing parameter according to a feeding order of each of the plurality of printed circuit boards fed after the solder mask is cleaned.

6. The solder printing apparatus of claim 1, wherein the control unit includes a processor configured to obtain a different printing parameter for each of the plurality of printed circuit boards according to the cleaning cycle count set for the solder mask and transmit a signal instructing to perform solder printing according to the different printing parameter obtained for each of the plurality of printed circuit boards.

7. The solder printing apparatus of claim 1, wherein the control unit includes,
a memory device configured to store a number of printed circuit board feeding times and the cleaning cycle count,
a communication circuit configured to be connected to and communicate with the printed circuit board feeding unit, the solder paste printing unit, and the solder mask cleaning unit,
a processor connected to the memory device and the communication circuit, and
a user interface connected to the memory device, the communication circuit, and the processor.

8. A solder printing apparatus comprising:
a printed circuit board feeding unit configured to sequentially feed a plurality of printed circuit boards;
a solder paste printing unit configured to locate a solder mask on each of the plurality of printed circuit boards sequentially fed by the printed circuit board feeding unit and print solder paste on each of the plurality of printed circuit boards;
a solder mask cleaning unit configured to clean the solder mask; and
a processor connected to the solder paste printing unit and the solder mask cleaning unit,
wherein the plurality of printed circuit boards include a first printed circuit board group and a second printed circuit board group, and
the processor is configured to,
obtain a first printing parameter and a second printing parameter according to a cleaning cycle count set for the solder mask, and
transmit information to the solder paste printing unit, the information instructing to print the solder paste to the first printed circuit board group according to the first printing parameter and print the solder paste to the second printed circuit board group according to the second printing parameter.

9. The solder printing apparatus of claim 8, wherein
each of the first and second printing parameters includes at least one selected from the group consisting of a squeegee down distance, a squeegee pressure, a squeegee speed, and a print count, and
the first printing parameter is different from the second printing parameter.

10. The solder printing apparatus of claim 8, wherein
a first squeegee pressure of the first printing parameter is less than a second squeegee pressure of the second printing parameter, and
a first squeegee speed of the first printing parameter is greater than a second squeegee speed of the second printing parameter.

11. The solder printing apparatus of claim 8, wherein each of the first and second printing parameters includes a snap-off distance between a corresponding one of the plurality of printed circuit boards and the solder mask.

12. The solder printing apparatus of claim 8, wherein each of the first and second printing parameters includes a separation speed at which the solder mask is separated from a corresponding one of the plurality of printed circuit boards after the solder paste is printed.

13. The solder printing apparatus of claim 8, wherein the first and second printing parameters are set according to a feeding order of the plurality of printed circuit boards fed after the solder mask is cleaned.

14. The solder printing apparatus of claim 8, wherein the second printed circuit board group includes more printed circuit boards than the first printed circuit board group.

15. A solder printing apparatus comprising:
a printed circuit board feeding unit configured to sequentially feed a plurality of printed circuit boards;
a solder paste printing unit configured to locate a solder mask on each of the plurality of printed circuit boards sequentially fed by the printed circuit board feeding unit and print solder paste on each of the plurality of printed circuit boards;
a solder mask cleaning unit configured to clean the solder mask; and
a processor connected to the solder paste printing unit and the solder mask cleaning unit,
wherein the processor is configured to
classify the plurality of printed circuit boards into first to n-th printed circuit board groups based on a remainder value when a number of printed circuit board feeding times is divided by a cleaning cycle count set for the solder mask, where “n” is a positive integer,
obtain first to n-th printing parameters respectively used to print the solder paste on the first to n-th printed circuit board groups, and
transmit information to the solder paste printing unit, the information instructing to print the solder paste to each of the first to n-th printed circuit board groups.

16. The solder printing apparatus of claim 15, wherein the processor is further configured to instruct the solder mask cleaning unit to clean the solder mask when the number of the printed circuit board feeding times is a multiple of the cleaning cycle count set for the solder mask.

17. The solder printing apparatus of claim 15, wherein
the first printed circuit board group among the first to n-th printed circuit board groups includes a first printed circuit board that is fed after the solder mask is cleaned, and
the n-th printed circuit board group among the first to n-th printed circuit board groups includes an n-th printed circuit board that is fed after the solder mask is cleaned.

18. The solder printing apparatus of claim 15, wherein
each of the first to n-th printing parameters includes at least one selected from the group consisting of a squeegee down distance, a squeegee pressure, a squeegee speed, and a print count, and
the first to n-th printing parameters are different from each other.

19. The solder printing apparatus of claim 15, wherein each of the first to n-th printing parameters includes a snap-off distance between a corresponding one of the plurality of printed circuit boards and the solder mask.

20. The solder printing apparatus of claim 15, wherein each of the first to n-th printing parameters includes a separation speed at which the solder mask is separated from a corresponding one of the plurality of printed circuit boards after the solder paste is printed.
